(19) United States
(12) Patent Application Publication
(10) Pub. No.: US 2026/0133489 A1
(43) Pub. Date: May 14, 2026

(54) PHOTOSENSITIVE RESIN COMPOSITION, PHOTOSENSITIVE RESIN LAYER AND SEMICONDUCTOR DEVICE USING THE SAME

(71) Applicant: SAMSUNG SDI CO., LTD., Yongin-si (KR)

(72) Inventors: Byeongwook PARK, Suwon-si (KR); Sang Soo KIM, Suwon-si (KR); Taek-Jin BAEK, Suwon-si (KR); Heekyoung KANG, Suwon-si (KR); Mingyum KIM, Suwon-si (KR); Jinhee KANG, Suwon-si (KR); Chungbeum HONG, Suwon-si (KR); Jiyu KIM, Suwon-si (KR); Hokyun RYU, Suwon-si (KR)

(21) Appl. No.: 19/338,919

(22) Filed: Sep. 24, 2025

(30) Foreign Application Priority Data
Nov. 11, 2024 (KR) 10-2024-0159480

(51) Int. Cl. G03F 7/038; H01L 23/498

(52) U.S. Cl. CPC G03F 7/0387; H10W 70/69

(57) ABSTRACT

Provided are a photosensitive resin composition including an alkali soluble resin; a photopolymerizable compound; a photoinitiator; and a solvent, wherein the alkali soluble resin includes a polymer including a structural unit represented by Chemical Formula 1 and a polymer including a structural unit represented by Chemical Formula 2, and the polymer including a structural unit represented by Chemical Formula 1 and the polymer including a structural unit represented by Chemical Formula 2 are included in a weight ratio of about 1:1 to about 1:2, a photosensitive resin layer manufactured using the same, and a semiconductor device including the photosensitive resin layer. In Chemical Formula 1 and Chemical Formula 2, each substituent is the same as defined in the detailed description.

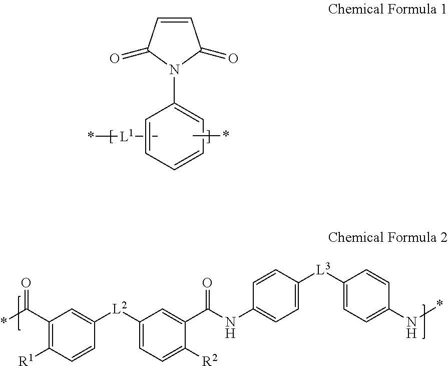

### CROSS-REFERENCE TO RELATED APPLICATION

The present application claims priority to and the benefit of Korean Patent Application No. 10-2024-0159480, filed on Nov. 11, 2024, in the Korean Intellectual Property Office, the entire content of which is hereby incorporated by reference.

### BACKGROUND

### 1. Field

Embodiments of this disclosure relate to a photosensitive resin composition, a photosensitive resin layer using the same, and a semiconductor device.

### 2. Description of the Related Art

With the advent of an era of hyper-connected intelligence such as artificial intelligence, big data, internet of things (IoT) devices, self-driving cars, remote medical treatment, and the like, development and distribution of various electronic devices such as smartphones are being accelerated.

Accordingly, 5G communication technology capable of wirelessly transmitting ultra-high-speed and large-capacity data becomes significantly more important, and in addition.

A dielectric substrate used in frequency (Sub-6 and 28 GHz) bands for 5G communication, in order to minimize or reduce a propagation loss, utilizes a low dielectric constant (Dk) and a low dielectric loss factor (Df), which may not be satisfied by polyimide (PI), which is mainly used for conventional 4G LTE communication.

Ming-Chi Kuo, an analyst at TF International, expected in 2018 “modified polyimide (MPI) to replace a liquid crystal polymer (LCP) as a mainstream antenna technology for new iPhone model in the second half of the year,” which means that as a FCCL (Flexible Cupper Clad Laminate) manufacturing process was structured with a production line of using a polyimide film (an existing process), because module manufacturers would prefer to perform the existing process rather than modifying the equipment to a LCP-using process, he hoped that MPI (Modified PI) would be quickly developed and applied. In addition, this suggests that MPI to complement or address the drawbacks of LCP has already been being developed.

The desire to develop polyimide precursor resins or other types (or kinds) of resins having low dielectric constant (Dk) and dielectric loss factor (Df) has been rapidly increasing recently.

### SUMMARY

Some example embodiments of the present disclosure provide a photosensitive resin composition including an alkali soluble resin having a low dielectric constant (Dk) and a low dielectric loss factor (Df).

Some example embodiments provide a photosensitive resin layer manufactured using the photosensitive resin composition.

Some example embodiments provide a semiconductor device including the photosensitive resin layer.

According to some example embodiments, a photosensitive resin composition includes an alkali soluble resin; a photopolymerizable compound; a photoinitiator; and a solvent, wherein the alkali soluble resin includes a polymer including a structural unit represented by Chemical Formula 1 and a polymer including a structural unit represented by Chemical Formula 2, and the polymer including a structural unit represented by Chemical Formula 1 and the polymer including a structural unit represented by Chemical Formula 2 are included in a weight ratio of about 1:1 to about 1:2.

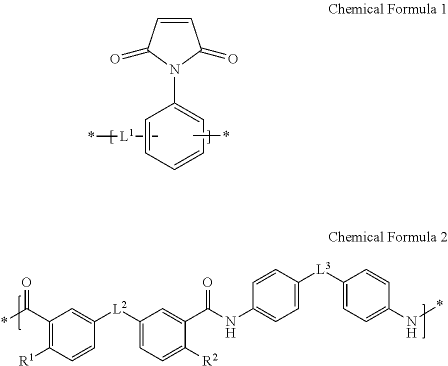

In Chemical Formula 1 and Chemical Formula 2,
L¹ is a substituted or unsubstituted C1 to C20 alkylene group, a substituted or unsubstituted C6 to C20 arylene group, or a combination thereof,
L² is a single bond (e.g., a single covalent bond), *—O—*, *—S—*, *—C≡C—*, *—C(═O)—*, *—NR⁰—* (wherein R⁰ is a substituted or unsubstituted C1 to C10 alkyl group), a substituted or unsubstituted C1 to C20 alkylene group, a substituted or unsubstituted C6 to C20 arylene group, a substituted or unsubstituted C2 to C20 heterocyclic linking group, or a combination thereof,
L³ is *—O—*, *—S—*, *—C≡C—*, *—C(═O)—*, *—NR⁰—* (wherein R⁰ is a substituted or unsubstituted C1 to C10 alkyl group), or a combination thereof, and
R¹ and R² are each independently represented by Chemical Formula R,

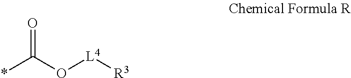

wherein, in Chemical Formula R,
R³ is a (meth)acrylate group, and
L⁴ is a substituted or unsubstituted C1 to C20 alkylene group.

The polymer including the structural unit represented by Chemical Formula 1 may include a functional group represented by Chemical Formula S at at least one of both terminal ends (e.g., two terminal ends).

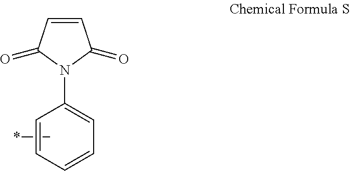

The polymer including the structural unit represented by Chemical Formula 1 may include a functional group represented by Chemical Formula S at one of both terminal ends (e.g., two terminal ends), and the other may be a hydrogen atom (e.g., may include a hydrogen at the other of the two terminal ends).

The photoinitiator may be included in an amount of about 2 wt % to about 5 wt % based on a total amount of the photosensitive resin composition.

The photosensitive resin composition may include the photopolymerizable compound in an amount of about 5 to about 20 parts by weight, the photoinitiator in an amount of about 3 parts by weight to about 10 parts by weight, and the solvent in an amount of about 100 to about 500 parts by weight, based on 100 parts by weight of the resin.

The photosensitive resin composition may further include a photosensitizer, a radical scavenger, a silane-based coupling agent, an organic acid, or a combination thereof.

The photosensitive resin composition may be a negative type (or kind) photosensitive resin composition.

Some example embodiments provide a photosensitive resin layer manufactured using the photosensitive resin composition.

The photosensitive resin layer may be a semiconductor redistribution layer insulating film (e.g., a semiconductor redistribution layer electrically insulating film).

Some example embodiments provide a semiconductor device including the photosensitive resin layer.

Other embodiments of the present disclosure are included in the following detailed description.

The alkali soluble resin in the photosensitive resin composition according to some example embodiments includes polymers having different structures at a set or specific weight ratio, thereby reducing the dielectric constant (Dk) and dielectric loss factor (Df).

### DETAILED DESCRIPTION

Hereinafter, embodiments of the present disclosure are described in more detail. However, these embodiments are examples, and this disclosure is not limited thereto.

As used herein, if (e.g., when) specific definition is not otherwise provided, the term “alkyl group” refers to a C1 to C20 alkyl group, the term “alkenyl group” refers to a C2 to C20 alkenyl group, the term “cycloalkenyl group” refers to a C3 to C20 cycloalkenyl group, the term “heterocycloalkenyl group” refers to a C3 to C20 heterocycloalkenyl group, the term “aryl group” refers to a C6 to C20 aryl group, the term “arylalkyl group” refers to a C7 to C20 arylalkyl group, the term “alkylene group” refers to a C1 to C20 alkylene group, the term “arylene group” refers to a C6 to C20 arylene group, the term “alkylarylene group” refers to a C7 to C20 alkylarylene group, the term “heteroarylene group” refers to a C3 to C20 heteroarylene group, and the term “alkoxylene group” refers to a C1 to C20 alkoxylene group.

As used herein, if (e.g., when) specific definition is not otherwise provided, the term “substituted” refers to replacement of at least one hydrogen of a compound by a substituent selected from a halogen atom (F, Cl, Br, or I), a C1 to C20 alkyl group substituted with a halogen atom such as a trifluoromethyl group, a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, if (e.g., when) specific definition is not otherwise provided, the term “hetero” refers to inclusion of at least one heteroatom of N, O, S, and P, in the chemical formula.

As used herein, if (e.g., when) specific definition is not otherwise provided, the term “(meth)acrylate” refers to both “acrylate” and “methacrylate.”

As used herein, if (e.g., when) a definition is not otherwise provided, the term “combination” refers to mixing or copolymerization. Also, the term “copolymerization” means block copolymerization, alternating copolymerization, or random copolymerization, and the term “copolymer” means a block copolymer, an alternating copolymer, or a random copolymer.

As used herein, if (e.g., when) specific definition is not otherwise provided, an unsaturated bond includes not only a plurality of bonds between carbon and carbon atoms, but also those including other molecules, such as a carbonyl bond and/or an azo bond.

In the chemical formula of the present specification, unless a specific definition is otherwise provided, hydrogen is bonded at the position if (e.g., when) a chemical bond is not drawn where supposed to be given.

As used herein, if (e.g., when) a definition is not otherwise provided, “*” refers to a linking part between the same or different atoms, or chemical formulas. As a market for wafer level packaging (WLP) and panel level packaging (PLP) grows, a photosensitivity material for a redistribution layer (RDL) is increasingly used. As the photosensitivity material, a photosensitivity polyimide resin, a photosensitivity benzocyclobutene (BCB) resin, a photosensitivity phenol resin, and/or the like are currently used, and the photosensitivity polyimide resin, which is able to satisfy both processability and reliability, is mainly used.

In embodiments, as the redistribution layer becomes multilayered and performs high-speed processing, because high-frequency signals are more lost, a design of reducing the dielectric loss of the package material is needed.

Embodiments of the present disclosure relate to a photosensitive resin composition, a photosensitive resin layer formed by using the same, and a semiconductor device including the photosensitive resin layer. Polyimide (PI) or polybenzoxazole (PBO) resins are mainly used to secure film properties such as elongation and Tg (glass transition temperature), which are important for reliability, as key elements of photosensitive resin compositions used as semiconductor circuit protection films. The photosensitive resin composition including the resin secures excellent protective film properties by using it together with other photocrosslinkable monomers, photopolymerization initiators, and/or the like. In order to implement excellent patterns, the photosensitive resin composition should have or is required to have excellent sensitivity properties without leaving residues, and storage stability at room temperature for more than two weeks is desired or required. High frequencies should or must be used to improve the processing speed of electronic devices, and materials having low dielectric constant (Dk) and dielectric loss (Df) are utilized or required to prevent or reduce transmission speed loss at this time.

An object of embodiments of the present disclosure is to provide a photosensitive resin composition capable of ensuring low dielectric loss while facilitating negative pattern formation. As the redistribution layer becomes multilayered and high-speed processing is performed, there are cases where high-frequency signals are lost, and thus a design that lowers the dielectric loss of the package material is required. The inventors of the present disclosure have been able to lower the dielectric loss by mixing the polymer including a structural unit represented by Chemical Formula 1 with the polymer including a structural unit represented by Chemical Formula 2.

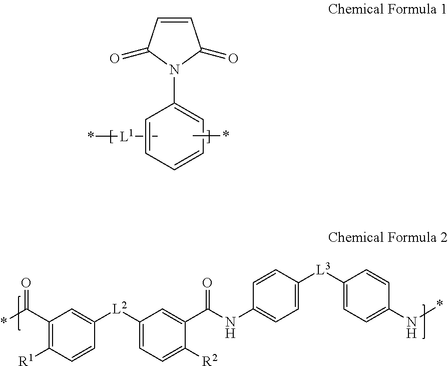

In Chemical Formula 1 and Chemical Formula 2,
L¹ is a substituted or unsubstituted C1 to C20 alkylene group, a substituted or unsubstituted C6 to C20 arylene group, or a combination thereof,
L² is a single bond (e.g., a single covalent bond), *—O—*, *—S—*, *—C≡C—*, *—C(═O)—*, *—NR⁰—* (wherein R⁰ is a substituted or unsubstituted C1 to C10 alkyl group), a substituted or unsubstituted C1 to C20 alkylene group, a substituted or unsubstituted C6 to C20 arylene group, a substituted or unsubstituted C2 to C20 heterocyclic linking group, or a combination thereof,
L³ is *—O—*, *—S—*, *—C≡C—*, *—C(═O)—*, *—NR⁰—* (wherein R⁰ is a substituted or unsubstituted C1 to C10 alkyl group), or a combination thereof, and
R¹ and R² are each independently represented by Chemical Formula R,

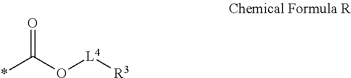

wherein, in Chemical Formula R,
R³ is a (meth)acrylate group, and
L⁴ is a substituted or unsubstituted C1 to C20 alkylene group.

Hereinafter, each component is described in more detail.

### (A) Resin

The polymer including the structural unit represented by Chemical Formula 1 and the polymer including a structural unit represented by Chemical Formula 2 may be included in a weight ratio of about 1:1 to about 1:2. If (e.g., when) the alkaline soluble resin is controlled to such a composition, the dielectric constant and dielectric loss can be reduced.

For example, the polymer including the structural unit represented by Chemical Formula 1 and the polymer including a structural unit represented by Chemical Formula 2 may be included in a weight ratio of about 1:1 to about 1:1.5, for example, a weight ratio of about 1:1. In embodiments, the dielectric constant and dielectric loss may be further reduced.

For example, the polymer including the structural unit represented by Chemical Formula 1 may include at at least one of both terminal ends (e.g., two terminal ends) a functional group represented by Chemical Formula S.

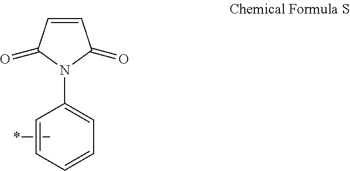

For example, the polymer including the structural unit represented by Chemical Formula 1 may include a functional group represented by Chemical Formula S at one of both terminal ends (e.g., at one of two terminal ends), and the other may be a hydrogen atom (e.g., hydrogen at may be at the other of the two terminal ends).

The polymer comprising the structural unit represented by Chemical Formula may be mixed with a polyamic acid and/or polyamic ester-based resin, and the polyamic acid and/or polyamic ester-based resin may be a resin polymerized with a diamine hydride compound and a diamine compound, and may include, for example, a structural unit represented by Chemical Formula 3.

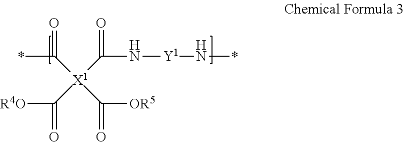

In Chemical Formula 3,
X¹ is a moiety derived from the dianhydride compound,
Y¹ is a moiety derived from the diamine compound, and
R⁴ and R⁵ are each independently a substituted or unsubstituted C1 to C20 alkyl group, a substituted or unsubstituted C3 to C20 cycloalkyl group, a substituted or unsubstituted C6 to C20 aryl group, or a substituted or unsubstituted C2 to C20 heterocyclic group.

For example, R⁴ and R⁵ may each independently be a C1 to C20 alkyl group substituted or unsubstituted with a (meth)acrylate group.

If (e.g., when) the polyamic acid or polyamic ester resin including the structural unit represented by Chemical Formula 3 is mixed with the polymer including the structural unit represented by Chemical Formula 1, an adhesive strength to a metal layer (for example, a copper layer, a silicon layer, and/or a titanium layer) may be greatly easily improved while minimizing or reducing dielectric loss, and it may be easily applied to a negative type (or kind) composition to greatly improve the developability. In general, the copper layer in the semiconductor redistribution layer includes a small amount of titanium in addition to copper and/or silicon, and a resin having the above structure is desirable in improving adhesive strength with the titanium. Accordingly, compared to a photosensitive resin composition using a resin not having the above structure, a photosensitive resin composition according to some example embodiments may have excellent adhesive strength with the copper layer and/or silicon layer in the semiconductor redistribution layer while at the same time having a low dielectric loss rate.

In general, resins having a closed ring structure have a problem in that film properties are slightly reduced if (e.g., when) cured at low temperatures, but polyamic acid or polyamic ester resins including a structural unit represented by Chemical Formula 3 include an ester linkage and, as described below, further include a divalent fused ring of a resonance structure as a linkage group, and thus they can greatly contribute to lowering the dielectric loss factor. The photosensitive resin composition according to some example embodiments, which is used as an alkali soluble resin by mixing the above resins with the polymer including the structural unit represented by Chemical Formula 1, may be suitable or optimized for low-temperature curing and may provide an insulating film (e.g., an electrically insulating film such as, for example, a cured film) having low dielectric loss factor and excellent sensitivity characteristics.

For example, L¹ may be represented by Chemical Formula 4.

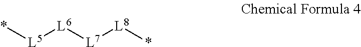

In Chemical Formula 4,
L⁵ and L⁸ are each independently a substituted or unsubstituted C1 to C20 alkylene group, and
L⁶ and L⁷ are each independently a substituted or unsubstituted C6 to C20 arylene group.

For example, the dihydride compound may further include a compound represented by Chemical Formula D.

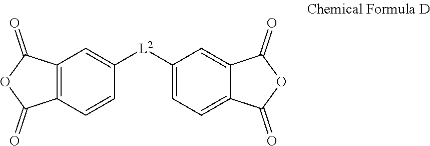

In Chemical Formula D,
L² is a single bond (e.g., a single covalent bond), *—O—*, *—S—*, *—C≡C—*, *—C(═O)—*, *—NR⁰—* (wherein R⁰ is a substituted or unsubstituted C1 to C10 alkyl group), a substituted or unsubstituted C1 to C20 alkylene group, a substituted or unsubstituted C6 to C20 arylene group, a substituted or unsubstituted C2 to C20 heterocyclic linking group, or a combination thereof.

For example, if (e.g., when) L² is *—C≡C—*, heat resistance characteristics, adhesive strength, and reliability of the insulating film (curing film) may be further improved.

For example, the compound represented by Chemical Formula D may include a compound represented by Chemical Formula D-1, a compound represented by Chemical Formula D-2, or a combination thereof.

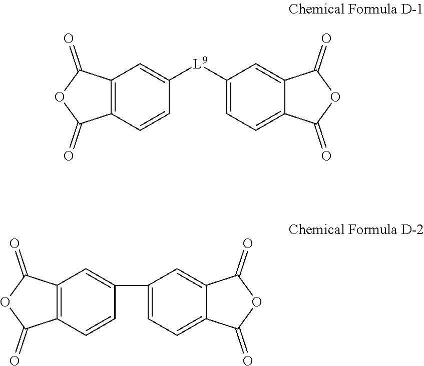

In Chemical Formula D-1,
L⁹ is *—O—*, *—S—*, *—C≡C—*, *—C(═O)—*, *—NR⁰—* (wherein R⁰ is a substituted or unsubstituted C1 to C10 alkyl group), a substituted or unsubstituted C1 to C20 alkylene group, a substituted or unsubstituted C6 to C20 arylene group, a substituted or unsubstituted C2 to C20 heterocyclic linking group, or a combination thereof.

For example, the compound represented by Chemical Formula D-1 may be represented by Chemical Formula D-1-1 or Chemical Formula D-1-2.

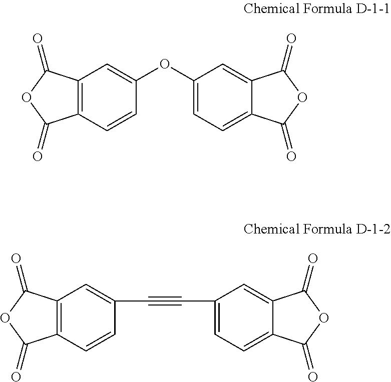 [SMILES: O=C1OC(=O)c2cc(Oc3ccc4c(c3)C(=O)OC4=O)ccc21 ; O=C1OC(=O)c2cc(C#Cc3ccc4c(c3)C(=O)OC4=O)ccc21]

For example, the diamine compound may include a compound represented by Chemical Formula E.

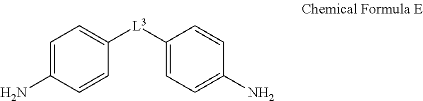

In Chemical Formula E,
L³ is *—O—*, *—S—*, *—C≡C—*, *—C(═O)—*, *—NR⁰—* (wherein R⁰ is a substituted or unsubstituted C1 to C10 alkyl group), or a combination thereof.

For example, the diamine compound may further include a compound represented by Chemical Formula F.

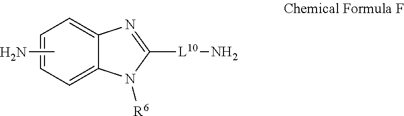

In Chemical Formula F,
R⁶ is a hydrogen atom or a substituted or unsubstituted C1 to C20 alkyl group,
L¹⁰ is a substituted or unsubstituted C6 to C20 arylene group or a substituted or unsubstituted divalent fused ring, and
the divalent fused ring is represented by Chemical Formula G,

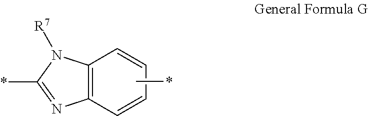

wherein, in Chemical Formula G,
R⁷ is a hydrogen atom or a substituted or unsubstituted C1 to C20 alkyl group.

If (e.g., when) the diamine compound includes a compound represented by Chemical Formula E and/or the compound represented by Chemical Formula F, it may be suitably or desirably lower the dielectric loss factor, and further, the compound represented by Chemical Formula E and the compound represented by Chemical Formula F may be included in a molar ratio of about 3:7 to about 7:3, for example, about 50:50, in which case the dielectric loss factor may be significantly lowered.

For example, the compound represented by Chemical Formula F may include a compound represented by Chemical Formula F-1, a compound represented by Chemical Formula F-2, or a combination thereof.

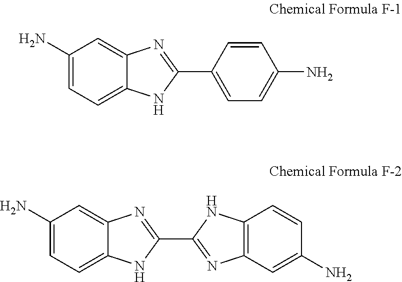 [SMILES: Nc1ccc(-c2nc3cc(N)ccc3[nH]2)cc1 ; Nc1ccc2[nH]c(-c3nc4cc(N)ccc4[nH]3)nc2c1]

For example, the polymer including a structural unit represented by Chemical Formula 2 may be a polymer in which the diamine hydride compound and the diamine compound are polymerized at a molar ratio of about 30:70 to about 70:30, for example, about 50:50.

A weight average molecular weight (Mw) of the alkali soluble resin including the polymer including the structural unit represented by Chemical Formula 1 and the polymer including a structural unit represented by Chemical Formula 2 may be about 3,000 g/mol to about 300,000 g/mol. If (e.g., when) the weight average molecular weight of the alkali soluble resin is within the above range, suitable or sufficient physical properties can be obtained, and the solubility in organic solvents is improved, thereby making handling easy.

### (B) Photopolymerizable Compound

The photosensitive resin composition according to some example embodiments may further include a photopolymerizable compound. The photopolymerizable compound may be a single compound or a mixture of two different compounds.

The photopolymerizable compound may be a compound including at least two functional groups represented by Chemical Formula 5.

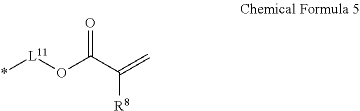

In Chemical Formula 5,
R⁸ is a hydrogen atom or a substituted or unsubstituted C1 to C10 alkyl group, and
L¹¹ is a single bond (e.g., a single covalent bond) or a substituted or unsubstituted C1 to C10 alkylene group.

For example, the compound including at least two functional groups represented by Chemical Formula 5 may include two to six functional groups represented by Chemical Formula 5. In embodiments, suitable or sufficient polymerization can be induced during exposure in the pattern formation process to form a pattern having excellent heat resistance, light resistance, and chemical resistance.

For example, the compound including at least two functional groups represented by Chemical Formula 5 may be a compound represented by any one selected from Chemical Formula 6 to Chemical Formula 8, but is not necessarily limited thereto.

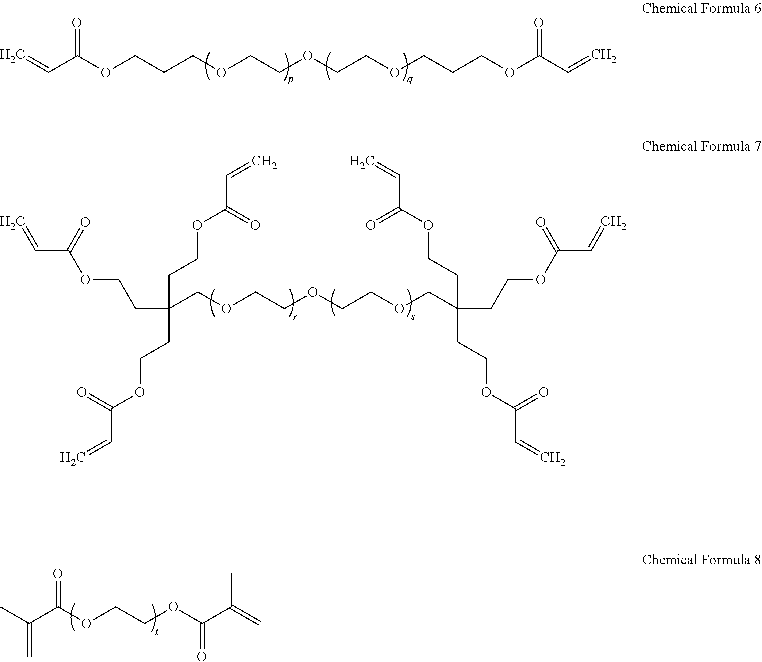

In Chemical Formula 6 to Chemical Formula 8, p, q, r, s, and t are each independently an integer of 1 to 10.

If (e.g., when) the photopolymerizable compound is a mixture of two different compounds, the other one of the two compounds may be a mono- or multi-functional ester compound of (meth)acrylic acid having at least one ethylenically unsaturated double bond.

The mono- or multi-functional ester compound of (meth)acrylic acid having at least one ethylenically unsaturated double bond may be for example, ethylene glycoldi(meth)acrylate, diethylene glycoldi(meth)acrylate, triethylene glycoldi(meth)acrylate, propylene glycoldi(meth)acrylate, neopentylglycoldi(meth)acrylate, 1,4-butanedioldi(meth)acrylate, 1,6-hexanedioldi(meth)acrylate, bisphenol A di(meth)acrylate, pentaerythritoldi(meth)acrylate, pentaerythritoltri(meth)acrylate, pentaerythritoltetra(meth)acrylate, pentaerythritolhexa(meth)acrylate, dipentaerythritoldi(meth)acrylate, dipentaerythritoltri(meth)acrylate, dipentaerythritolpenta(meth)acrylate, dipentaerythritolhexa(meth)acrylate, bisphenol A epoxy(meth)acrylate, ethylene glycolmonomethylether (meth)acrylate, trimethylolpropanetri(meth)acrylate, tris(meth)acryloyloxyethylphosphate, novolac epoxy(meth)acrylate, or a combination thereof.

Non-limiting examples of commercially available products of the monofunctional or multifunctional ester compound of (meth)acrylic acid having at least one ethylenically unsaturated double bond are as follows. Examples of the mono-functional ester of (meth)acrylic acid may include Aronix M-101®, M-1110, and M-114® (Toagosei Chemistry Industry Co., Ltd.); KAYARAD TC-110S®, and TC-120S® (Nippon Kayaku Co., Ltd.); V-158®, and V-2311® (Osaka Organic Chemical Ind., Ltd.), and the like. Examples of a di-functional ester of (meth)acrylic acid may include Aronix M-210@, M-240®, and M-6200® (Toagosei Chemistry Industry Co., Ltd.), KAYARAD HDDA®, HX-220®, and R-604® (Nippon Kayaku Co., Ltd.), V-260®, V-312®, V-335 HP® (Osaka Organic Chemical Ind., Ltd.), and the like. Examples of a tri-functional ester of (meth)acrylic acid may include Aronix M-309®, M-400®, M-405®, M-450®, M-7100®, M-1 8030®, and M-8060® (Toagosei Chemistry Industry Co., Ltd.), KAYARAD TMPTA®, KAYARAD DPCA-20®, KAYARAD DPCA-30®, KAYARAD DPCA-60®, and KAYARAD DPCA-120® (Nippon Kayaku Co., Ltd.), V-295®, V-300®, V-360®, V-GPT®, V-3PA®, and V-400@ (Osaka Yuki Kayaku Kogyo Co. Ltd.), and the like. These may be used alone or as a mixture of two or more.

The photopolymerizable compound may be used after being treated with an acid anhydride to provide better developability.

The photopolymerizable compound may be included in an amount of about 5 parts by weight to about 20 parts by weight, or, for example, about 7 parts by weight to about 15 parts by weight based on 100 parts by weight of the resin. If the photopolymerizable compound is included within the above ranges, curing occurs suitably or sufficiently, reliability is excellent, heat resistance, light resistance, and chemical resistance of the pattern are improved, and resolution and adhesion are also improved.

### (C) Photoinitiator

The photosensitive resin composition according to some example embodiments may further include a photoinitiator.

For example, the photoinitiator may be included in an amount of about 2 wt % to about 5 wt %, or, for example, about 2 wt % to about 4 wt %, based on a total amount of the photosensitive resin composition. If (e.g., when) the photoinitiator is included within the above ranges, the dielectric loss may be maintained low while at the same time not lowering the sensitivity characteristics. Even if the alkali soluble resin includes a polymer including a structural unit represented by the chemical formula 1 and a polymer including a structural unit represented by the chemical formula 2 in a weight ratio of about 1:1 to about 1:2, if the photoinitiator is not included in the above range, it may be difficult to maintain excellent sensitivity characteristics despite low dielectric loss.

The photoinitiator may be an acetophenone-based compound, a benzophenone-based compound, a thioxanthone-based compound, a benzoin-based compound, a triazine-based compound, an oxime-based compound, and/or the like. Examples of the acetophenone-based compound may be 2,2′-diethoxy

acetophenone, 2,2′-dibutoxy acetophenone, 2-hydroxy-2-methylpropinophenone, p-t-butyltrichloro acetophenone, p-t-butyldichloro acetophenone, 4-chloroacetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone-based compound may be benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone-based compound may be thioxanthone, 2-chlorothioxanthone, 2-methylthioxanthone, isopropyl thioxanthone, 2,4-diethyl thioxanthone, 2,4-diisopropyl thioxanthone, and the like.

Examples of the benzoin-based compound may be benzoin, benzoin methyl ether, benzoin ethyl ether, benzoin isopropyl ether, benzoin isobutyl ether, benzyl dimethyl ketal, and the like.

Examples of the triazine-based compound may be 2,4,6-trichloro-s-triazine, 2-phenyl 4,6-bis(trichloromethyl)-s-triazine, 2-(3′, 4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloromethyl)-s-triazine, bis(trichloromethyl)-6-styryl-s-triazine, 2-(naphtho1-yl)-4,6-bis(trichloromethyl)-s-triazine, 2-(4-methoxynaphtho1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime compounds may include an O-acyloxime compound, 2-(O-benzoyloxime)-1-[4-(phenylthio)phenyl]-1,2-octanedione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Specific examples of the O-acyloxime compounds may include 1,2-octanedione, 2-dimethylamino-2-(4-methylbenzyl)-1-(4-morpholin-4-yl-phenyl)-butan-1-one, 1-(4-phenylsulfanylphenyl)-butane-1,2-dione-2-oxime-O-benzoate, 1-(4-phenylsulfanylphenyl)-octane-1,2-dione-2-oxime-O-benzoate, 1-(4-phenylsulfanylphenyl)-octane-1-one oxime-O-acetate, 1-(4-phenylsulfanylphenyl)-butane-1-one oxime-O-acetate, and the like.

The photoinitiator may include a carbazole-based compound, a diketone-based compound, a sulfonium borate-based compound, a diazo-based compound, an imidazole-based compound, a biimidazole-based compound, and a fluorene-based compound, in addition to the above compounds.

The photopolymerization initiator may be included in an amount of about 3 parts by weight to about 20 parts by weight, for example, about 3 parts by weight to about 10 parts by weight, or, for example, about 4 parts by weight to about 9 parts by weight based on 100 parts by weight of the resin. If (e.g., when) the photoinitiator is included within the above ranges, photopolymerization occurs suitably or sufficiently as described above, thereby preventing or reducing a decrease in sensitivity characteristics and improving transmittance (e.g., data transmittance).

### (D) Solvent

The solvent may be a material that is compatible with, but does not react with, the alkali soluble resin, the photopolymerizable compound, and the photoinitiator.

Examples of the solvent may include alcohols such as methanol, ethanol, and the like; ethers such as dichloroethylether, n-butylether, diisoamylether, methylphenylether, tetrahydrofuran, and the like; glycolethers such as ethylene glycolmonomethylether, ethylene glycolmonoethylether, ethylene glycoldimethylether, and the like; cellosolveacetates such as methylcellosolveacetate, ethylcellosolveacetate, diethylcellosolveacetate, and the like; carbitols such as methylethylcarbitol, diethylcarbitol, diethylene glycolmonomethylether, diethylene glycolmonoethylether, diethylene glycoldimethylether, diethylene glycolethylmethylether, diethylene glycoldiethylether, and the like; propylene glycolalkyletheracetates such as propylene glycolmethyletheracetate, propylene glycolpropyletheracetate, and the like; aromatic hydrocarbons such as toluene, xylene, and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxy acetic acid alkyl esters such as oxy methyl acetate, oxy ethyl acetate, oxy butyl acetate, and the like; alkoxy acetic acid alkyl esters such as methoxy methyl acetate, methoxy ethyl acetate, methoxy butyl acetate, ethoxy methyl acetate, ethoxy ethyl acetate, and the like; 3-oxypropionic acid alkyl esters such as 3-oxymethyl propionate, 3-oxyethyl propionate, and the like; 3-alkoxypropionic acid alkyl esters such as 3-methoxymethyl propionate, 3-methoxyethyl propionate, 3-ethoxyethyl propionate, 3-ethoxymethyl propionate, and the like; 2-oxypropionic acid alkyl esters such as 2-oxymethyl propionate, 2-oxyethyl propionate, 2-oxypropyl propionate, and the like; 2-alkoxypropionic acid alkyl esters such as 2-methoxymethyl propionate, 2-methoxyethyl propionate, 2-ethoxyethyl propionate, 2-ethoxymethyl propionate, and the like; 2-oxy-2-methylpropionic acid esters such as 2-oxy-2-methylmethyl propionate, 2-oxy-2-methylethyl propionate, and the like, monooxy monocarboxylic acid alkyl esters of 2-alkoxy-2-methyl alkyl propionates such as 2-methoxy-2-methylmethyl propionate, 2-ethoxy-2-methylethyl propionate, and the like; esters such as 2-hydroxyethyl propionate, 2-hydroxy-2-methylethyl propionate, hydroxy ethyl acetate, 2-hydroxy-3-methyl methyl butanoate, and the like; ketonate esters such as ethyl pyruvate, and the like. Additionally, a high boiling point solvent such as N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, 3-methyl benzoate, ethylene carbonate, propylene carbonate, phenyl cellosolve acetate, and the like may be also used.

The solvent may be included in an amount of about 100 to about 500 parts by weight based on 100 parts by weight of the resin. If the solvent is included within the above range, the photosensitive resin composition has suitable or appropriate viscosity, thereby resulting in excellent processability if (e.g., when) manufacturing photosensitive resin layers.

### (E) Other Additives

The photosensitive resin composition according to some example embodiments may further include other additives.

The photosensitive resin composition may include an additive such as a diacid (e.g., malonic acid), an alkanolamine (e.g., 3-amino-1,2-propanediol), a photosensitizer, a leveling agent, a radical scavenger, a silane-based coupling agent, a surfactant, an organic acid, an epoxy compound, a thermal latent acid generator, a development control agent, a curing agent, or a combination thereof, in order to prevent or reduce an occurrence, likelihood, or degree of stains and/or spots during coating, to achieve leveling properties, and/or to prevent or reduce the generation of residues due to non-development. An amount of these additives used can be easily adjusted depending on suitable or desired physical properties.

For example, the organic acid may improve electrical characteristics of the photosensitive resin composition according to some example embodiments, ultimately contributing to reducing the dielectric constant and dielectric loss.

For example, the organic acid may include citric acid. The citric acid may play a role in improving ion conductivity in an electrolyte system, which may affect the electrical characteristics, for example, if (e.g., when) the citric acid is doped into an alginic acid-based solid biopolymer electrolyte, the electrolyte exhibits a non-Debye behavior, which may be analyzed through a composite dielectric constant (ε*) and a complex electrical modulus (M*). This result suggests that the citric acid induces the abnormal dielectric behavior in the system in which the citric acid is included, and if such a citric acid is added to a photosensitive resin composition, the citric acid may affect its dielectric characteristics through chemical interaction and structural change of a resin, ultimately contributing to reducing the dielectric constant and the dielectric loss.

For example, the silane-based coupling agent may have a reactive substituent such as a vinyl group, carboxyl group, methacryloxy group, isocyanate group, or epoxy group to improve adhesion to the substrate, and has a different structure from the silane compound.

Examples of the silane-based coupling agent may include trimethoxysilylbenzoic acid, γ-methacryloxypropyltrimethoxysilane, vinyltriacetoxysilane, vinyltrimethoxysilane, γ-isocyanatepropyltriethoxysilane, γ-glycidoxypropyltrimethoxysilane, β-(3,4-epoxycyclohexyl)ethyltrimethoxysilane, and the like. These may be used alone or in a mixture of two or more.

The silane-based coupling agent may be included in an amount of about 0.01 parts by weight to about 10 parts by weight based on 100 parts by weight of the photosensitive resin composition. If the silane-based coupling agent is included within the above range, adhesion, storage properties, and the like are improved.

For example, the surfactant is added to prevent or reduce film thickness unevenness and/or improve developability, and may include a fluorine-based surfactant and/or a silicone-based surfactant.

Examples of the fluorine-based surfactant may be a commercial fluorine-based surfactant such as BM-1000®, BM-1100®, and the like of BM Chemie Inc.; MEGAFACE F 142D®, MEGAFACE F 172®, MEGAFACE F 173@, MEGAFACE F 183®, MEGAFACE F 554®, and the like of Dainippon Ink Kagaku Kogyo Co., Ltd.; FLUORAD FC-135@, FLUORAD FC-170C®, FLUORAD FC-430@, FLUORAD FC-431@, and the like of SUMITOMO 3M Co., Ltd.; SURFLON S-112®, SURFLON S-113®, SURFLON S-131®, SURFLON S-141®, SURFLON S-145®, and the like of Asahi Glass Co., Ltd.; SH-28PA®, SH-190®, SH-193®, SZ-6032®, SF-8428®, and the like of Toray Silicone Co., Ltd.

The silicone-based surfactant may be a commercial silicone-based surfactant such as BYK-307, BYK-333, BYK-361N, BYK-051, BYK-052, BYK-053, BYK-067A, BYK-077, BYK-301, BYK-322, BYK-325, BYK-378, and the like of BYK Chem.

The surfactant may be used in an amount of about 0.001 parts by weight to about 5 parts by weight based on 100 parts by weight of the photosensitive resin composition. If the surfactant is included within the above range, coating uniformity can be ensured, stains cannot (or do not or substantially do not) occur, and wetting on ITO substrates and/or glass substrates, Si wafers and/or SiNₓ wafers, and/or Cu substrates can be improved.

In embodiments, the photosensitive resin composition further includes an epoxy compound to improve adhesion and the like with a substrate. Examples of the epoxy compound may include a phenol novolac epoxy compound, a tetramethyl biphenyl epoxy compound, a bisphenol A epoxy compound, an alicyclic epoxy compound, or a combination thereof.

The epoxy compound may be used in an amount of about 0.01 part by weight to about 5 parts by weight based on 100 parts by weight of the resin composition. If (e.g., when) the epoxy compound is included within the above range, storage properties, adhesive force, and other properties can be improved.

In embodiments, the photosensitive resin composition may further include a thermal latent acid generator. Examples of the thermal latent acid generator may include arylsulfonic acids such as p-toluenesulfonic acid and benzenesulfonic acid; perfluoroalkylsulfonic acids such as trifluoromethanesulfonic acid, trifluorobutanesulfonic acid, and/or the like; alkylsulfonic acids such as methanesulfonic acid, ethanesulfonic acid, butanesulfonic acid, and/or the like; or a combination thereof, but is not limited thereto.

Furthermore, the photosensitive resin composition may include other additives such as an antioxidant, a stabilizer, and/or the like in a set or predetermined amount unless they deteriorate properties of the photosensitive resin composition.

Some example embodiments provide a photosensitive resin layer, for example a semiconductor redistribution layer insulating film (e.g., a semiconductor redistribution layer electrically insulating film) manufactured by exposing, developing, and curing the photosensitive resin composition described above.

The method of manufacturing the photosensitive resin layer is as follows.

### (1) Coating and Film Formation

The photosensitive resin composition is coated to have a suitable or desired thickness on a substrate such as a glass substrate and/or ITO substrate, Si wafer and/or SiNx wafer, Cu substrate, and/or the like which undergoes a set or predetermined pretreatment, using a spin and/or slit coating method, a roll coating method, a screen-printing method, an applicator method, and/or the like, and is heated at about 70° C. to about 150° C. for about 1 minute to 10 minutes to remove a solvent and thereby to form a film.

### (2) Exposure

After providing a mask to form a necessary or desired pattern on the obtained photosensitive resin layer, exposure is performed by irradiating an actinic ray of 200 nm to 500 nm. As a light source used for irradiation, a low-pressure mercury lamp, a high-pressure mercury lamp, an ultra-high pressure mercury lamp, a metal halide lamp, an argon gas laser, and/or the like may be used, and in some cases, an X-ray, an electron beam, and/or the like may be used.

The exposure dose varies depending on the type (or kind), mixing amount, and dry film thickness of each component of the composition, but is less than 500 mJ/cm² (based on a 365 nm sensor) if (e.g., when) using a high-pressure mercury lamp.

### (3) Development

In the development method, following the exposure step, alkali aqueous solution or an organic solvent is used as a developer to dissolve and remove unnecessary or undesired parts, leaving only the exposed parts remaining to form a pattern.

### (4) Post-Processing

There is a post-heating process to obtain a pattern excellent in terms of heat resistance, light resistance, adhesion, crack resistance, chemical resistance, high strength, and storage stability of the image pattern obtained by development in the above process. For example, after development, it can be heated in a nitrogen atmosphere in an oven at about 200° C. to about 400° C. for 1 hour or more.

Some example embodiments provide an electronic device including the photosensitive resin layer (e.g., a semiconductor redistribution layer insulating film such as, for example, a semiconductor redistribution layer electrically insulating film).

Hereinafter, embodiments of the present disclosure are illustrated in more detail with reference to examples. However, the following examples are only examples of the present disclosure, and the present disclosure is not limited by the following examples.

### EXAMPLES

### Synthesis of Resin

### Synthesis Example 1

While passing nitrogen through a four-necked flask equipped with a stirrer, a temperature controller, a nitrogen gas injection device, and a condenser, 0.58 mol of a dianhydride monomer represented by Chemical Formula A was added to 600 g of γ-butyrolactone (GBL), and then, 1.22 mol of 2-hydroxyethylmethacrylate (HEMA) was added thereto, and while stirring the mixture at room temperature, 1.16 mol of pyridine was added thereto to obtain a reaction mixture. The reaction mixture was reacted at room temperature for 16 hours and then, cooled to −10° C., and a solution prepared by dissolving 1.17 mol of dicyclohexylcarbodiimide (DCC) and 250 g of GBL was added in a dropwise fashion thereto over 30 minutes. After additionally stirring the mixture for 5 minutes, a solution of 0.54 mol of a diamine monomer represented by Chemical Formula B and 300 g of GBL were added thereto for 40 minutes and then, additionally stirred for 2 hours. After reacting at room temperature for 1 hour, 30 g of ethanol was added and stirred for 1 hour. Subsequently, GBL was added to the reaction solution to have a solid content of 18% and then, added to 3 liters of ethanol to obtain precipitates. A polymer was separated therefrom through filtration, dissolved in 1.5 liters of tetrahydrofuran (THF), and then, added in a dropwise fashion to 30 liters of water to form precipitates, and the precipitates were separated through filtration and vacuum-dried. By drying at 50° C. under reduced pressure for 24 hours or more, a polyimide precursor resin (polyamic ester-based resin) including a structural unit represented by Chemical Formula C was prepared. (Chemical Formula A and Chemical Formula B are polymerized in a molar ratio of 1:1)

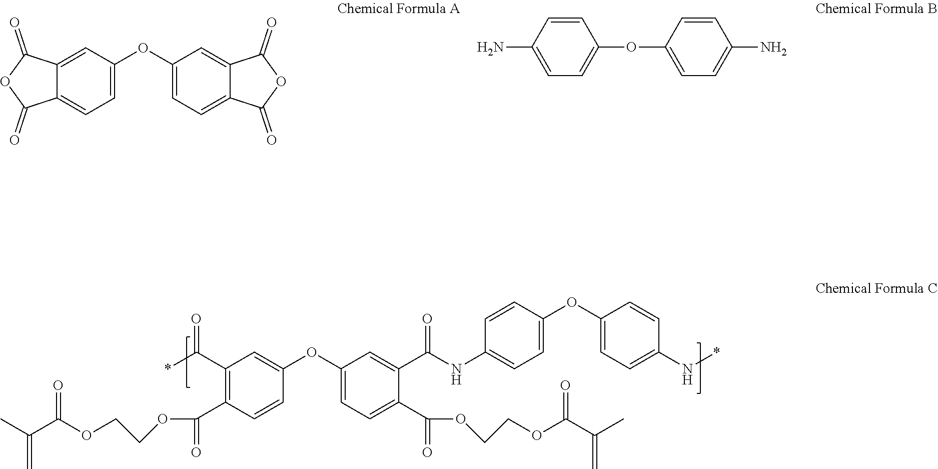

### Synthesis Example 2

MIR-3000 (Nippon Kayaku)

### Preparation of Photosensitive Resin Composition

### Examples 1 to 7 and Comparative Examples 1 to 6

Each photosensitive resin composition was prepared according to the compositions shown in Table 1. Specifically, an alkali soluble resin and a photopolymerizable compound were mixed, and a photoinitiator, a photosensitizer, a radical scavenger, a silane-based coupling agent, an organic acid, and a solvent were added thereto and stirred sufficiently. Then, the negative type (or kind) photosensitive resin compositions were obtained by filtering through a 0.45 μm polypropylene resin filter.

TABLE 1
unit: wt %

| | | | | | | | | Compar- | Compar- | Compar- | Compar- | Compar- | Compar- |
|---|---|---|---|---|---|---|---|---|---|---|---|---|---|
| | | | | | | | | ative | ative | ative | ative | ative | ative |
| | Exam- | Exam- | Exam- | Exam- | Exam- | Exam- | Exam- | Exam- | Exam- | Exam- | Exam- | Exam- | Exam- |
| | ple 1 | ple 2 | ple 3 | ple 4 | ple 5 | ple 6 | ple 7 | ple 1 | ple 2 | ple 3 | ple 4 | ple 5 | ple 6 |
| Alkali | 19.34 | 19.32 | 16.12 | 15.99 | 15.84 | 15.84 | 15.84 | 32.23 | — | 29.01 | 25.79 | 22.56 | 13.55 |
| soluble | | | | | | | | | | | | | |
| resin 1 | | | | | | | | | | | | | |
| Alkali | 12.89 | 12.91 | 16.12 | 15.99 | 15.84 | 15.84 | 15.84 | — | 32.23 | 3.22 | 6.45 | 9.67 | 18.68 |
| soluble | | | | | | | | | | | | | |
| resin 2 | | | | | | | | | | | | | |
| Photo- | 3.58 | 3.58 | 3.58 | 3.55 | 3.52 | 3.52 | 3.52 | 3.58 | 3.58 | 3.58 | 3.58 | 3.58 | 3.58 |
| poly- | | | | | | | | | | | | | |
| merizable | | | | | | | | | | | | | |
| compound | | | | | | | | | | | | | |
| Photo- | 1.45 | 1.45 | 1.45 | 2.24 | 3.17 | 4.23 | 5.07 | 1.45 | 1.45 | 1.45 | 1.45 | 1.45 | 1.45 |
| initiator | | | | | | | | | | | | | |
| Photo- | 2.90 | 2.90 | 2.90 | 2.90 | 2.90 | 2.90 | 2.90 | 2.90 | 2.90 | 2.90 | 2.90 | 2.90 | 2.90 |
| sensitizer | | | | | | | | | | | | | |
| Radical | 0.48 | 0.48 | 0.48 | 0.48 | 0.48 | 0.48 | 0.48 | 0.48 | 0.48 | 0.48 | 0.48 | 0.48 | 0.48 |
| scavenger | | | | | | | | | | | | | |
| Silane- | 0.81 | 0.81 | 0.81 | 0.80 | 0.79 | 0.78 | 0.78 | 0.81 | 0.81 | 0.81 | 0.81 | 0.81 | 0.81 |
| based | | | | | | | | | | | | | |
| coupling | | | | | | | | | | | | | |
| agent | | | | | | | | | | | | | |
| Organic | 0.16 | 0.16 | 0.16 | 0.16 | 0.16 | 0.16 | 0.16 | 0.16 | 0.16 | 0.16 | 0.16 | 0.16 | 0.16 |
| acid | | | | | | | | | | | | | |
| Solvent | 52.54 | 52.54 | 52.54 | 52.12 | 51.61 | 50.55 | 49.8 | 52.54 | 52.54 | 52.54 | 52.53 | 52.54 | 52.54 |
| 1 | | | | | | | | | | | | | |
| Solvent | 5.85 | 5.85 | 5.84 | 5.77 | 5.69 | 5.7 | 5.61 | 5.85 | 5.85 | 5.85 | 5.85 | 5.85 | 5.85 |
| 2 | | | | | | | | | | | | | |

Alkali soluble resin 1: the resin of Synthesis Example 1
Alkali soluble resin 2: the resin of Synthesis Example 2
Photopolymerizable compound: tetraethylene glycol dimethacrylate (TCI)
Photoinitiator: PBG-450 (Changzhou Tronly)
Photosensitizer: N-phenyl diethanolamine (MORIN)
Radical scavenger: CX-1790 (Solvay)
Silane-based coupling agent: KBM-403 (Shinetsu)
Organic acid: citric acid (SAMCHUN)
Solvent 1: γ-butyrolactone (DAEJUNG)
Solvent 2: dimethylsulfoxide (DAEJUNG)

### Evaluation

The photosensitive resin compositions according to Examples 1 to 7 and Comparative Examples 1 to 6 were coated on an 8-inch Cu wafer and baked at 100° C. for 4 minutes to obtain each 7 μm-thick film. Then, the film was exposed with Nikon's i10C and developed with cyclopentanone for 20 seconds and 20 seconds in a puddle type (or kind) to form a 20 μm hole pattern. Then, the developed wafer was cured in a 220° C. oven in a nitrogen atmosphere for 2 hours.

Eop evaluation: The exposure dose at which a 20 μm hole is formed was confirmed using critical dimension-scanning electron microscope (CD-SEM), and the results are shown in Table 2.

Evaluation of dielectric loss factor (Df): The manufactured film (cured film) was dried at 130° C. for 30 minutes and then aged for 24 hours at a constant temperature and humidity chamber maintained at 23° C. and 50% relative humidity to perform pretreatment. Then, the dielectric characteristics were measured at a frequency of 10 GHz using the Split Post Dielectric Resonator (SPDR) measurement method using Keysight's ENA, and the results are shown in Table 2.

Reliability evaluation: The manufactured film (cured film) is subjected to 2000 cycles of thermal cycle (−55° C. to 125° C.), which is the reliability condition. Then, field emission-scanning electron microscopy (FE-SEM) was used to check whether cracks were generated between PI and Cu, and the results are shown in Table 2.

TABLE 2

| | Eop (msec) | Df (10 GHz) | Reliability |
|---|---|---|---|
| Example 1 | 244 | 0.009 | OK |
| Example 2 | 215 | 0.006 | OK |
| Example 3 | 178 | 0.005 | OK |
| Example 4 | 456 | 0.006 | OK |
| Example 5 | 579 | 0.006 | OK |
| Example 6 | 358 | 0.006 | OK |
| Example 7 | 96 | 0.006 | OK |
| Comparative | 621 | 0.021 | OK |
| Example 1 | | | |
| Comparative | 151 | 0.033 | NG |
| Example 2 | | | |
| Comparative | 512 | 0.017 | OK |
| Example 3 | | | |
| Comparative | 433 | 0.014 | OK |
| Example 4 | | | |
| Comparative | 312 | 0.012 | OK |
| Example 5 | | | |
| Comparative | 208 | 0.039 | NG |
| Example 6 | | | |

Through Table 2, the photosensitive resin composition according to some example embodiments has a low dielectric loss factor while also having excellent sensitivity characteristics and reliability, and is therefore suitable for use as a composition for a semiconductor redistribution layer.

While the subject matter of this disclosure has been described in connection with what is presently considered to be practical example embodiments, it is to be understood that the present disclosure is not limited to the disclosed embodiments, but, on the contrary, is intended to cover various suitable modifications and equivalent arrangements included within the spirit and scope of the appended claims and equivalents thereof. Therefore, the aforementioned embodiments should be understood to be examples but not limiting the present disclosure in any way.

What is claimed is:

1. A photosensitive resin composition, comprising:
an alkali soluble resin;
a photopolymerizable compound;
a photoinitiator; and
a solvent,
wherein the alkali soluble resin comprises a polymer comprising a structural unit represented by Chemical Formula 1 and a polymer comprising a structural unit represented by Chemical Formula 2, and the polymer comprising a structural unit represented by Chemical Formula 1 and the polymer comprising a structural unit represented by Chemical Formula 2 are included in a weight ratio of about 1:1 to about 1:2: 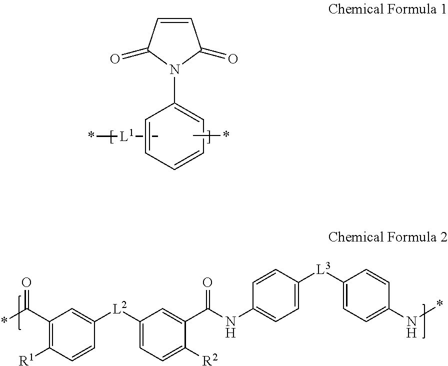
wherein in Chemical Formula 1 and Chemical Formula 2,
L¹ is a substituted or unsubstituted C1 to C20 alkylene group, a substituted or unsubstituted C6 to C20 arylene group, or a combination thereof,
L² is a single bond, *—O—*, *—S—*, *—C≡C—*, *—C(═O)—*, *—NR⁰—* (wherein R⁰ is a substituted or unsubstituted C1 to C10 alkyl group), a substituted or unsubstituted C1 to C20 alkylene group, a substituted or unsubstituted C6 to C20 arylene group, a substituted or unsubstituted C2 to C20 heterocyclic linking group, or a combination thereof,
L³ is *—O—*, *—S—*, *—C≡C—*, *—C(═O)—*, *—NR⁰—* (wherein R⁰ is a substituted or unsubstituted C1 to C10 alkyl group), or a combination thereof, and
R¹ and R² are each independently represented by Chemical Formula R, 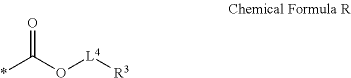
wherein in Chemical Formula R,
R³ is a (meth)acrylate group, and
L⁴ is a substituted or unsubstituted C1 to C20 alkylene group.

2. The photosensitive resin composition as claimed in claim 1, wherein:
the polymer comprising the structural unit represented by Chemical Formula 1 comprises a functional group represented by Chemical Formula S at at least one of both terminal ends:

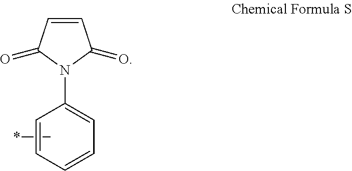

3. The photosensitive resin composition as claimed in claim 2, wherein:
the polymer comprising the structural unit represented by Chemical Formula 1 comprises a functional group represented by Chemical Formula S at one of both terminal ends, and the other is a hydrogen atom.

4. The photosensitive resin composition as claimed in claim 1, wherein:
the photoinitiator is included in an amount of about 2 wt % to about 5 wt % based on a total amount of the photosensitive resin composition.

5. The photosensitive resin composition as claimed in claim 1, wherein:
the photosensitive resin composition comprises,
based on 100 parts by weight of the resin 100 parts by weight,
about 5 parts by weight to about 20 parts by weight of the photopolymerizable compound,
about 3 parts by weight to about 20 parts by weight of the photoinitiator, and
about 100 parts by weight to about 500 parts by weight of the solvent.

6. The photosensitive resin composition as claimed in claim 1, wherein:
the photosensitive resin composition further comprises a photosensitizer, a radical scavenger, a silane-based coupling agent, an organic acid, or a combination thereof.

7. The photosensitive resin composition as claimed in claim 1, wherein:
the photosensitive resin composition is a negative type photosensitive resin composition.

8. A photosensitive resin layer manufactured using the photosensitive resin composition as claimed in claim 1.

9. The photosensitive resin layer as claimed in claim 8, wherein:
the photosensitive resin layer is a semiconductor redistribution layer insulating film.

10. A semiconductor device comprising the photosensitive resin layer as claimed in claim 8.
